(19) United States
(12) Patent Application Publication
(10) Pub. No.: US 2010/0117703 A1
(43) Pub. Date: May 13, 2010

(54) MULTI-MODE SINGLE-ENDED CMOS INPUT BUFFER

(76) Inventors: Zhipeng Zhu, Austin, TX (US); Axel Thomsen, Austin, TX (US)

Correspondence Address: ZAGORIN O'BRIEN GRAHAM LLP (026), 7600B NORTH CAPITAL OF TEXAS HIGHWAY, SUITE 350, AUSTIN, TX, 78731-1191, US

(21) Appl. No.: 12/269,984

(22) Filed: Nov. 13, 2008

(51) Int. Cl. H03K 3/00; G05F 1/10

(52) U.S. Cl. 327/206; 327/205; 327/535

(57) ABSTRACT

Techniques reduce the effects of power supply noise on a signal provided by a single-ended complementary metal-oxide semiconductor (i.e., CMOS) input buffer circuit capable of receiving an input signal having one of a variety of acceptable formats, while generating the signal to have substantially the same duty cycle as the input signal. The techniques include one or more of AC coupling, hysteresis, and voltage biasing applied to the input buffer circuit.

### BACKGROUND

1. Field of the Invention

This invention relates to integrated circuits and more particularly to integrated circuit structures configured to receive input signals.

2. Description of the Related Art

A typical input buffer of an integrated circuit receives a signal from a terminal (e.g., port, pad, or other suitable input or input/output structure) of the integrated circuit. The typical input buffer is designed to meet specifications associated with a particular signal format and may not be compatible with input signal formats associated with other specifications. In addition, the typical input buffer may not preserve the duty cycle of the input signal and may be susceptible to noise from an external power supply that at least partially powers the input buffer. For example, the signal delivered by the input buffer may vary in amplitude or in delay in response to noise variation of the external power supply voltage.

### SUMMARY

Techniques reduce the effects of power supply noise on a signal provided by a single-ended complementary metal-oxide semiconductor (i.e., CMOS) input buffer circuit capable of receiving an input signal having one of a variety of acceptable formats, while generating the signal to have substantially the same duty cycle as the input signal. The techniques include one or more of AC coupling, hysteresis, and voltage biasing applied to the input buffer circuit.

In at least one embodiment of the invention, an apparatus includes a terminal configured to receive a single-ended input signal. The apparatus includes a first device having a first type and being coupled to a first node and a first power supply node. The apparatus includes a second device having a second type and being coupled to the first node and a second power supply node. The apparatus includes a first circuit configured to provide a first bias voltage to the first device and configured to AC couple the terminal to the first device. The apparatus includes a second circuit configured to provide a second bias voltage to the second device and configured to AC couple the terminal to the second device. The first and second devices are configured to generate a signal on the first node in response to the AC coupled versions of the input signal.

In at least one embodiment of the invention, a method includes providing a first high-pass filtered version of a signal received on a single-ended terminal to a first node. The method includes providing a second high-pass filtered version of the signal to a second node. The method includes configuring in a first saturation region of operation a first device coupled to the first node. The method includes configuring in a second saturation region of operation a second device coupled to the second node. The method includes generating a signal on a third node by the first and second devices in response to the first and second high-pass-filtered versions of the signal.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a circuit diagram of an exemplary input buffer consistent with at least one embodiment of the invention.

FIG. 2 illustrates an exemplary waveform consistent with a portion of the circuit of FIG. 1.

FIG. 3 illustrates a circuit diagram of an exemplary hysteresis circuit consistent with at least one embodiment of the invention.

The use of the same reference symbols in different drawings indicates similar or identical items.

### DESCRIPTION OF THE PREFERRED EMBODIMENT(S)

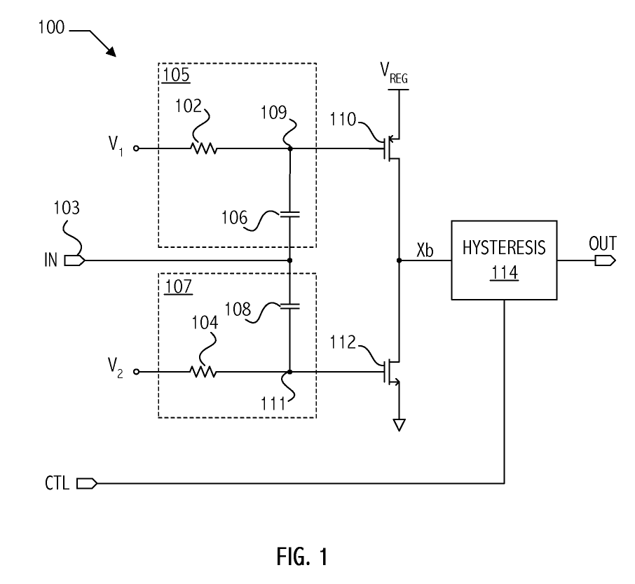

Referring to FIG. 1, an exemplary input buffer 100 receives an input signal (e.g., IN) from a terminal (e.g., terminal 103), which is a port, pad, or other suitable input structure, of an integrated circuit. The input signal may have one of a variety of acceptable signal formats. For example, IN may be any one of a Low Voltage Complementary Metal Oxide Semiconductor (LVCMOS) signal, which is referenced to an approximately 3.3V power supply voltage, a Stub Series Terminate Logic (SSTL) signal, which may be referenced to an approximately 3.3V, 2.5V, or 1.8V power supply voltage, a High-Speed Transceiver Logic (HSTL) which may be referenced to an approximately 1.5V power supply voltage, or a signal compliant with another suitable signal standard. Accordingly, input buffer 100 satisfies the voltage requirements of a variety of formats by being capable of providing an appropriate output signal (e.g., OUT) referenced to an on-chip regulated voltage in response to receiving an input signal having any signal swing (i.e., peak-to-peak voltage, V_{PP}) in the range of acceptable signal swings (e.g., approximately 0.4V<=V_{PP}<=3.6V). In at least one embodiment of input buffer 100, the output signal, OUT has a duty cycle (e.g., a duty cycle of approximately 48% to approximately 52%) substantially the same as the duty cycle of an input signal (e.g., approximately 50% duty cycle with a V_{PP} of approximately 1.4V and a frequency less than or equal to approximately 350 MHz).

In at least one embodiment of input buffer 100, terminal 103 is AC coupled to a CMOS inverter formed by p-type device 110 and n-type device 112. As referred to herein, AC coupling (e.g., capacitive coupling) is the coupling of one circuit to another circuit or node through a capacitor or other device that substantially passes the varying portion (i.e., AC) of an electrical signal and substantially attenuates the static (i.e., DC) characteristics of the electrical signal. For example, signals received by terminal 103 are high-pass filtered (e.g., by circuits 105 and 107) to generate substantially varying signals or high-frequency signals (e.g., the signals on nodes 109 and 111, respectively). Note that circuits 105 and 107 are exemplary only and other AC coupling circuits may be used.

Since an inverter circuit formed by devices 110 and 112 is AC coupled to terminal 103, the power supply coupled to the inverter circuit can be independent of the input signal and need not be coupled to a voltage supply that is common to the source of the input signal received on terminal 103. Accordingly, in at least one embodiment of input buffer 100, the inverter circuit is coupled to a regulated voltage supply node (e.g., V_{REG}), thereby improving rejection of noise on power supply nodes as compared to input buffers that are coupled to a voltage supply that is common to the source of the input signal (e.g., an external power supply node). In addition, the input signal, IN, can be any one of several input signal formats having different reference voltages (i.e., different V_{DD} values). For example, IN may be any one of an LVCMOS signal referenced to an approximately 3.3V power supply voltage, an SSTL signal referenced to one of an approximately 3.3V, 2.5V or 1.8V power supply voltage, an HSTL signal referenced to an approximately 1.5V power supply voltage, or other acceptable signal compliant with another suitable power supply voltage. Note that the inverter circuit formed by devices 110 and 112 is exemplary only and other suitable inverting or non-inverting buffer circuits may be used.

In at least one embodiment of input buffer 100, circuits 105 and 107 are each coupled to different bias voltage nodes. For example, circuit 105 is coupled to receive a first regulated voltage that biases node 109 with a voltage level that configures device 110 in a saturation region of operation. Similarly, circuit 103 is coupled to receive a second regulated voltage that biases node 111 with a voltage level that configures device 112 in a saturation region of operation. By separately biasing the n-type and p-type devices of the inverter circuit to only operate in their respective saturation regions of operation, each of those devices has an increased sensitivity to signals with a small voltage swing on node 109 and node 111, respectively. As a result of those increased sensitivities, input buffer 100 is increasingly able to preserve the duty cycle of the input signal.

Since circuits 105 and 107 each include a feedback resistor (e.g., resistors 102 and 104, respectively), the inverter formed by devices 110 and 112 effectively receives signals (e.g., the signals on nodes 109 and 111, respectively) that decay over time towards their respective DC bias voltages (e.g., V₁ and V₂, respectively) as a function of the respective time constants (i.e., τ=RC) of circuits 105 and 107.

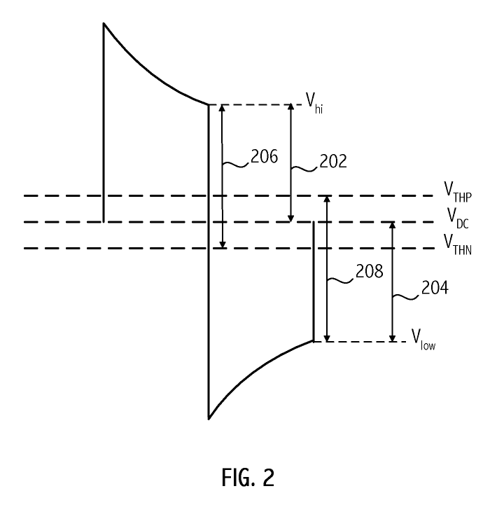

Note that if the signals on nodes 109 and 111 glitch (e.g., due to noise on a power supply node, reflections, ringing, or other sources of noise), the output of the inverter circuit (e.g., Xb) may switch as if it received a signal edge on terminal 103 even though the input signal IN is not actually transitioning between a high value and a low value. Accordingly, in at least one embodiment, input buffer 100 is designed to include voltage margin. Referring to FIGS. 1 and 2, in at least one embodiment, the values for R and C of circuits 105 and 107 are designed to form a filter with a large enough time constant to maintain sufficient voltage margin between the high and low voltage levels (e.g., Vₕᵢ and V_{low}) of the filtered version of the input signal and the trigger point(s) (i.e., switching point(s)) of the inverter formed by devices 110 and 112 to prevent switching of the output signal of the inverter circuit in response to glitches or other noise on the filtered version of the input signal. Increases in the time constant result in increased margin. In at least one embodiment of input buffer 100, an input signal has a target 50% duty cycle because a 50% duty cycle provides substantially equal voltage margins for the high and low voltage levels of the filtered version of the input signal and increases the minimum magnitude of the voltage margins for the high and low voltage levels.

In at least one embodiment of input buffer 100, terminal 103 is configured to receive an input clock signal (e.g., a clock signal in the MHz or hundreds of MHz range) having a duty cycle of approximately 50% (e.g., in the range between approximately 40% and approximately 60%). The target voltage margin required by a corresponding signal specification is relatively large. For example, a particular input signal format (e.g., LVTTL/LVCMOS) requires that a level between 2.0V and 3.6V be considered as a ‘1,’ i.e., requires a 1.6V margin. However, the range of duty cycle specification for the input clock signal is approximately 40% to 60% (e.g., for a target duty cycle of 50%). If the input clock signal is a 3.6V signal having a 60% duty cycle, the actual margin between Vₕᵢ and V_{DC} is 3.6V×0.40=1.44V, which is less than the target margin of 1.6V.

Accordingly, in at least one embodiment, input buffer 100 implements a hysteresis technique that increases the voltage margin between the voltage of Vₕᵢ and a voltage that triggers a transition of the output signal from Vₕᵢ to V_{low} and increases the margin between the voltage of V_{low} and a voltage that triggers a transition of the output signal from V_{low} to Vₕᵢ. In a typical inverter without hysteresis, the trigger point of the inverter is approximately V_{DC}, i.e., the output switches from high to low or from low to high when the input signal is approximately V_{REG}/2(e.g., V_{REG}/2=V_{DC}). Still referring to FIGS. 1 and 2, an exemplary signal (e.g., the signal on node Xb) generated by the inverter formed by devices 110 and 111 in response to a square wave input on IN has margin voltage 202 (i.e., approximately Vₕᵢ−V_{DC}) and margin voltage 204 (i.e., approximately V_{DC}−V_{low}) for transitioning from high to low and from low to high, respectively.

In at least one embodiment of input buffer 100, hysteresis circuit 114 increases the voltage margins to margin voltage 206 (i.e., approximately Vₕᵢ−V_{THN}) and margin voltage 208 (i.e., approximately V_{THP}−V_{low}) for transitioning from high to low and from low to high, respectively. As the voltage of the input signal increases from a low signal voltage level to a high signal voltage level, the input voltage value that is sufficient to trigger a switch of the logic output value is changed from V_{DC} to V_{DC}+V_{THP}. As the input signal is lowered from V_{REG} to GND, the input voltage value that is sufficient to trigger the switch of the logic output value is changed from V_{DC} to V_{DC}−V_{THN}. Accordingly, the voltage margins change from V_{DC}−V_{low} and Vₕᵢ−V_{DC} to V_{THP}−V_{low} and Vₕᵢ−V_{THN}, respectively.

In at least one embodiment of hysteresis circuit 114, the level of hysteresis is selectable from one of a plurality of hysteresis levels according to the value of a control signal (e.g., CTL), which may be a digital signal having one or more bits. The control signal may be supplied by a user from off-chip or from a previously configured memory storage element. A user of input buffer 100 may have knowledge of the quality of the input signal and may select one of several predetermined levels of hysteresis based thereon. In at least one embodiment of hysteresis circuit 114, four different levels of hysteresis are implemented (e.g., 0 mV, 50 mV, 100 mV, and 200 mV). For example, with 200 mV of hysteresis selected, the voltage swing of the input signal must be greater than 200 mV to trigger a transition of the logic value of the output signal of the inverter circuit and hysteresis circuit 300 changes corresponding trigger points of input buffer 100, accordingly. Note that in other embodiments of input buffer 100, other suitable levels of hysteresis may be used.

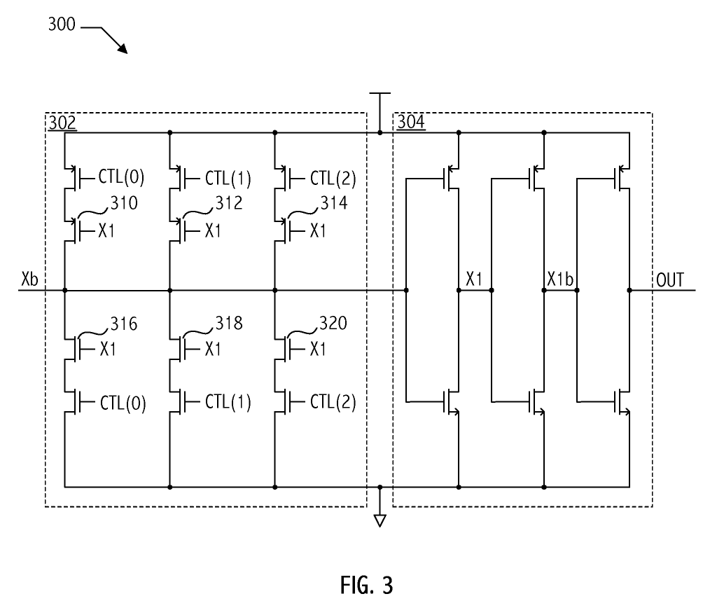

Referring to FIG. 3, an exemplary circuit portion (e.g., hysteresis circuit 300) includes a feedback portion 302 and buffer portion 304. Feedback portion 302 includes a plurality of selectively enabled pull-up devices (e.g., devices 310, 312, and 314) and a plurality of selectively enabled pull-down devices (e.g., devices 316, 318, and 320), each of which is responsive to a version of the output signal (e.g., X1). Individual devices of the pull-up devices and pull-down device pairs may be sized according to the selectable amount(s) of hysteresis being provided by hysteresis circuit 300. Feedback portion 302 receives a version of the output signal (e.g., X1) and implements the selected amount of hysteresis (e.g., as determined by the control signal CTL(2:0)) applied to signal Xb, as described above. Thus, in at least one embodiment of input buffer 100, hysteresis techniques increase the voltage margin between the high and low voltage levels of the filtered clock signal and the trigger point(s) (i.e., switching point(s)) of the inverter formed by devices 110 and 112 to reduce or prevent switching of the output signal in response to glitches or other noise on the filtered version of the input signal provided to the inverter. Buffer portion 304 includes one or more inverter circuits that are configured to provide an output signal (e.g., OUT) having target polarity with respect to the input signal, e.g., IN of FIG. 1, and a target signal strength. For example, in at least one embodiment, buffer portion 304 is sized to drive a relatively large capacitive load.

While circuits and physical structures are generally presumed, it is well recognized that in modern semiconductor design and fabrication, physical structures and circuits may be embodied in computer-readable descriptive form suitable for use in subsequent design, test or fabrication stages. Structures and functionality presented as discrete components in the exemplary configurations may be implemented as a combined structure or component. The invention is contemplated to include circuits, systems of circuits, related methods, and computer-readable medium encodings of such circuits, systems, and methods, all as described herein, and as defined in the appended claims. As used herein, a computer-readable medium includes at least disk, tape, or other magnetic, optical, semiconductor (e.g., flash memory cards, ROM), or electronic medium.

The description of the invention set forth herein is illustrative, and is not intended to limit the scope of the invention as set forth in the following claims. For example, although the input buffer of FIG. 1 is described with regard to LVCMOS-compliant, CMOS-compliant, SSTL-compliant input signals, the techniques described herein may be adapted to inputs compliant with other suitable signal standards. Note that hysteresis circuit 300 is exemplary only and that other suitable circuit configurations may be used to vary switching points of input buffer 100. In addition, note that terminal 103 may be coupled to electrostatic discharge protection circuitry (not shown) and/or other suitable circuitry. Variations and modifications of the embodiments disclosed herein may be made based on the description set forth herein, without departing from the scope and spirit of the invention as set forth in the following claims.

1. An apparatus comprising:
a terminal configured to receive an input signal;
a first device having a first type and being coupled to a first node and a first power supply node;
a second device having a second type and being coupled to the first node and a second power supply node;
a first circuit configured to provide a first bias voltage to the first device and configured to AC couple the terminal to the first device; and
a second circuit configured to provide a second bias voltage to the second device and configured to AC couple the terminal to the second device,
wherein the first and second devices are configured to generate a signal on the first node in response to AC coupled versions of the input signal.

2. The apparatus, as recited in claim 1,
wherein the first power supply node is a first regulated voltage node and the second power supply node is a ground node.

3. The apparatus, as recited in claim 1,
wherein the first bias voltage configures the first device in a first saturation region of operation, and
wherein the second bias voltage configures the second device in a second saturation region of operation.

4. The apparatus, as recited in claim 1, further comprising:
a hysteresis circuit coupled to the first node, the hysteresis circuit being configured to reduce sensitivity of an output signal to noise on the single-ended input signal.

5. The apparatus, as recited in claim 1, further comprising:
a hysteresis circuit coupled to the first node, the hysteresis circuit being configured to provide a first amount of hysteresis in response to a first value of one or more control signals and a second amount of hysteresis in response to a second value of the one or more control signals.

6. The apparatus, as recited in claim 5,
wherein the first and second devices form at least a portion of an inverter circuit,
wherein the hysteresis circuit is configured to increase a first trigger point of the inverter circuit to a second trigger point at least partially based on a first value of an output signal of the inverter circuit, and
wherein the hysteresis circuit is configured to decrease the first trigger point of the inverter circuit to a third trigger point at least partially based on a second value of the output signal.

7. The apparatus, as recited in claim 6, wherein the second and third trigger points are determined according to the one or more control signals.

8. The apparatus, as recited in claim 5, wherein the hysteresis circuit is configured to generate an output signal that switches from a first voltage level to a second voltage level in response to a transition of a first signal on the first node when the first signal on the first node has a voltage swing greater than a predetermined voltage level.

9. The apparatus, as recited in claim 8, wherein the predetermined voltage level is selected from a plurality of voltage levels according to the one or more control signals.

10. The apparatus, as recited in claim 5, wherein the one or more control signals are configured according to a value received from one or more of a second terminal, pin, fuse, or memory circuit.

11. The apparatus, as recited in claim 1, wherein the apparatus is configured to generate an output signal having approximately the same duty cycle as the single-ended input signal in response to the single-ended input signal being any one of a Low Voltage Complementary Metal Oxide Semiconductor (LVCMOS) signal, Stub Series Terminate Logic (SSTL) signal, and High-Speed Transceiver Logic (HSTL) signal.

12. The apparatus, as recited in claim 1, wherein the apparatus is configured to generate an output having approximately the same duty cycle as the single-ended input signal in response to the single-ended input signal having a voltage swing of approximately 0.4V and configured to generate an output having approximately the same duty cycle as the single-ended input signal in response to the single-ended input signal having a voltage swing of approximately 3.6V.

13. A method comprising:
providing a first high-pass filtered version of a signal received on a single-ended terminal to a first node;
providing a second high-pass filtered version of the signal to a second node;
configuring in a first saturation region of operation a first device coupled to the first node;
configuring in a second saturation region of operation a second device coupled to the second node; and
generating a signal on a third node by the first and second devices in response to the first and second high-pass-filtered versions of the signal.

14. The method, as recited in claim 13, further comprising:
applying a first amount of hysteresis to a signal on the third node in response to a first value of one or more control signals and a second amount of hysteresis in response to a second value of the one or more control signals.

15. The method, as recited in claim 13, wherein the first and second devices form at least a portion of an inverter circuit, and further comprising:
increasing a first trigger point of the inverter circuit to a second trigger point at least partially based on a first value of the signal on the third node; and
decreasing the first trigger point of the inverter circuit to a third trigger point at least partially based on a second value of the signal on the third node.

16. The method, as recited in claim 15, wherein the second and third trigger points are determined according to the one or more control signals.

17. The method, as recited in claim 13, wherein the signal on the third node switches from a first voltage level to a second voltage level in response to a transition of a first signal on the first node when the first signal on the first node has a voltage swing greater than a first predetermined voltage swing.

18. The method, as recited in claim 13, wherein the apparatus is configured to generate an output having approximately the same duty cycle as the single-ended input signal in response to the single-ended input signal being any one of a Low Voltage Complementary Metal Oxide Semiconductor (LVCMOS) signal, Stub Series Terminate Logic (SSTL) signal, and High-Speed Transceiver Logic (HSTL) signal.

19. The method, as recited in claim 13, wherein an output voltage generated at least partially based on the voltage on the third node has approximately the same duty cycle as the single-ended input signal in response to the single-ended input signal having a voltage swing of approximately 0.4V and the output voltage has approximately the same duty cycle as the single-ended input signal in response to the single-ended input signal having a voltage swing of approximately 3.6V.

20. An apparatus comprising:
a single-ended terminal;
a buffer means; and
means for substantially attenuating a DC component of a signal received by the buffer means from the single-ended terminal and for operating first and second devices of the buffer means in a saturation region of operation.

21. The apparatus, as recited in claim 20, further comprising:
means for selectively configuring first and second trigger points of the buffer means at least partially based on an output signal of the buffer means.
